(19) United States
(12) Patent Application Publication
(10) Pub. No.: US 2015/0098172 A1
(43) Pub. Date: Apr. 9, 2015

(54) Method and apparatus for securing a handheld electronic device to a dashboard

(71) Applicant: Douglas Benjamin Kankiewicz, Longmont, CO (US)

(72) Inventor: Douglas Benjamin Kankiewicz, Longmont, CO (US)

(21) Appl. No.: 14/505,480

(22) Filed: Oct. 2, 2014

Related U.S. Application Data
(60) Provisional application No. 62/003,498, filed on May 27, 2014.
(60) Provisional application No. 61/887,029, filed on Oct. 4, 2013.

(51) Int. Cl. H05K 7/14; H04R 3/00; H02J 7/02

(52) U.S. Cl. CPC H05K 7/1417; H02J 7/025; H04R 3/00; H04R 2499/13
USPC 361/679.01; 381/123

(57) ABSTRACT

A secure mounting device for connecting handheld electronic equipment securely to a control panel, including the dashboard of a vehicle, can include a cover panel, and a connecting component with a locking component, which can be inserted in a joint between the control panel and a radio or other control panel instrument, to lock in place in a locking surface. Additionally, the cover panel can hold an electronic device. The connecting component can be configured as a media box with a box cavity for storing an electronic device. The secure mounting device can also include a switchover device, which optionally keeps a vehicle audio system intact and fully functional, to switch back and forth between the vehicle audio system and external electronic devices, such that the secure mounting device functions as a docking station for electronic devices.

### CROSS-REFERENCE TO RELATED APPLICATIONS

This application claims the benefit of U.S. Provisional Application No. 62/003,498, filed May 27, 2014 and U.S. Provisional Application No. 61/887,029, filed Oct. 4, 2013.

### FIELD OF THE INVENTION

The present invention relates generally to the field of methods and devices for securing handheld mobile equipment to the dashboard of a vehicle.

### BACKGROUND OF THE INVENTION

Handheld and/ or portable electronic devices (e.g., digital media players, phones, smartphones, tablet computers, handheld readers, and similar devices) are becoming important and common tools. These tools are constantly in use, both at home and on the go.

However, with this frequency and variety of use comes the problem of proper protection. Without proper protection, a device may become damaged due to being dropped or by falling from an unsecured position. This damage may be permanent and cause loss of data or information and high replacement costs.

Particularly, when a user of a handheld electronic device is driving a vehicle, the problem of where to place the handheld electronic device becomes acutely manifest. Wearing the device in a clothing pocket is impractical, as retrieval during driving is difficult, and may also be unlawful. Traditional mounting devices can be difficult and impractical to install in the vehicle. Such traditional devices often can become dislodged and fall off while driving, creating a potentially hazardous situation.

As such, it may be appreciated that there continues to be a need for novel and improved methods and devices for securing a handheld electronic device to a dashboard.

### SUMMARY OF THE INVENTION

The foregoing needs are met, to a great extent, by the present invention, wherein in aspects of this invention, enhancements are provided to the existing models for connecting mobile devices to the dashboard of a vehicle.

In aspects of this invention, handheld electronic equipment can be mounted to the dashboard of a vehicle using a secure mounting device, composed of a cover panel, and a connecting component, which can be inserted in the joint between the dashboard and a radio or other dashboard component.

In related aspects of this invention, the cover panel can be made of any flexible and solid material, such as different types of plastics and metals.

In further related aspects of this invention, the cover panel material can be opaque, semi-transparent, or transparent.

In further related aspects of this invention, the cover panel can be placed anywhere on a common dashboard.

In further related aspects of this invention, the cover panel can open in any direction, slide in any direction, slide and tilt in any direction or be removable to gain access to the instrument that needs control, while optionally holding a handheld electronic device.

In further related aspects, the cover panel can be configured to hold an electronic device.

In further related aspects, the cover panel can include a display.

In further related aspects, the connecting component can be a media box, which is inserted into a cavity in the control panel, such that the media box further includes a box cavity, which can store an electronic device.

There has thus been outlined, rather broadly, certain embodiments of the invention in order that the detailed description thereof herein may be better understood, and in order that the present contribution to the art may be better appreciated. There are, of course, additional embodiments of the invention that will be described below and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of embodiments in addition to those described and of being practiced and carried out in various ways. In addition, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is a front perspective view of a secure mounting device mounted in a dashboard, according to an embodiment of the invention.

FIG. 2 is a cross-sectional side view of a secure mounting device mounted in a dashboard, according to an embodiment of the invention.

FIG. 3 is a front perspective view of a secure mounting device, according to an embodiment of the invention.

FIG. 4 is a front/side perspective view of a secure mounting device, according to an embodiment of the invention.

FIG. 5 is a top perspective view of a secure mounting device, according to an embodiment of the invention.

FIG. 6 is a cross-sectional top view of a part of a secure mounting device, according to an embodiment of the invention.

FIG. 7 is a cross-sectional top view of a part of a secure mounting device, according to an embodiment of the invention.

FIG. 8 is a cross-sectional top view of a part of a secure mounting device, according to an embodiment of the invention.

FIG. 9 is a cross-sectional top view of a part of a secure mounting device, according to an embodiment of the invention.

FIG. 10 is a cross-sectional top view of a part of a secure mounting device, according to an embodiment of the invention.

FIG. 11 is a cross-sectional top view of a secure mounting device, according to an embodiment of the invention.

FIG. 12 is a front view of a secure mounting device, according to an embodiment of the invention.

FIG. 13 is a front view of a secure mounting device, according to an embodiment of the invention.

FIG. 14 is a cross-sectional top view of a secure mounting device, according to an embodiment of the invention.

FIG. 15 is a top view of an installation of an audio switchover device, according to an embodiment of the invention.

FIG. 16 is a top view of an installation of an audio switchover device, according to an embodiment of the invention.

FIG. 17 is a front view of a secure mounting device, according to an embodiment of the invention.

FIG. 18 is a front view of a secure mounting device, according to an embodiment of the invention.

FIG. 19 is a front view of a secure mounting device, according to an embodiment of the invention.

FIG. 20 is a front view of a secure mounting device, according to an embodiment of the invention.

FIG. 21 is a side view of a secure mounting device, according to an embodiment of the invention.

FIG. 22 is a diagram of a switchover device, according to an embodiment of the invention.

FIG. 23 is a diagram of a switchover device, according to an embodiment of the invention.

FIG. 24 is a front view of a secure mounting device, according to an embodiment of the invention.

FIG. 25 is a center cut side view of a secure mounting device, according to an embodiment of the invention.

FIG. 26 is a front view of a secure mounting device, according to an embodiment of the invention.

FIG. 27 is a side view of a secure mounting device, according to an embodiment of the invention.

FIG. 28 is a front view of a secure mounting device, according to an embodiment of the invention.

FIG. 29 is a center-cut front view of a cover panel, according to an embodiment of the invention.

### DETAILED DESCRIPTION

Before describing the invention in detail, it should be observed that the present invention resides primarily in a novel and non-obvious combination of elements and process steps. So as not to obscure the disclosure with details that will readily be apparent to those skilled in the art, certain conventional elements and steps have been presented with lesser detail, while the drawings and specification describe in greater detail other elements and steps pertinent to understanding the invention.

The following embodiments are not intended to define limits as to the structure or method of the invention, but only to provide exemplary constructions. The embodiments are permissive rather than mandatory and illustrative rather than exhaustive.

In various embodiments of the invention, handheld electronic devices, including cellular phones, GPS navigation units, digital media players, phones, smartphones, tablet computers, handheld readers, display monitors, touchscreen devices and similar devices, can be mounted to the dashboard of a vehicle.

In related embodiments of this invention, a vehicle can include a car, a truck, a motorbike, a boat, an airplane, and other transportation devices that contain a dashboard in front of a driver or pilot.

In related embodiments of the invention, a control panel can include: a car dashboard, heater control unit, instrument panel, dashboard component or area, navigation unit, GPS, clock, music system, amplifier, radio, a dashboard found in any common vehicle, motorcycle, marine vehicle or airplane, or any other control device or control surface incorporated in an electronic or mechanical instrument. The control panel can include various instruments, gauges, and control components, such as lever, handles, buttons, etc. A control panel in the form of a vehicle dashboard can for example include instruments such as a radio, a navigation unit, and various other gauges and controls.

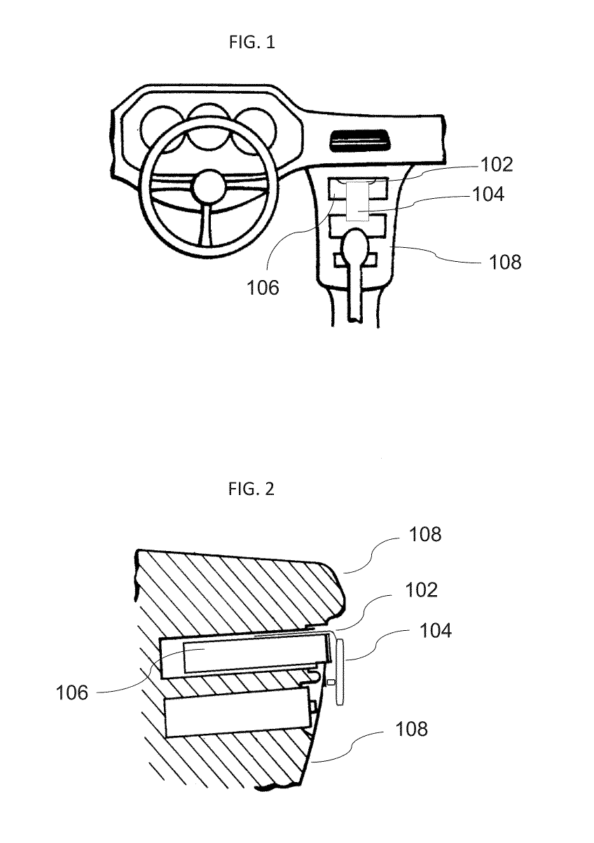

FIG. 1 shows a front view of an embodiment, wherein a connecting component 102 can be inserted in a joint on the control panel 108, for example in joint around an instrument 106, to allow a cover panel 104 to be placed in front of the instrument 106 and the control panel 108.

FIG. 2 shows a cross-sectional side-view of a related embodiment, wherein a connecting component 102 is flat and thin, such that it can be inserted in a joint on the control panel 108, around an instrument 106, to allow a cover panel 104 to be placed in front of the instrument 106 and the control panel 108.

In various related embodiments, a connecting component 102 can include any material that is flexible, with sufficient strength, and can fit in-between any given joint in a common dashboard or instrument panel, that can be secured behind utilizing any method, which the strap can penetrate through the crevices or joints of the instrument panel and be utilized as an anchor point for a mountable device or case that holds a device.

In a related embodiment, a connecting component 102 can be shaped, partially or fully as a strap, with a flat shape that will allow it to slide through a thin joint in a control panel 108. The strap can be made of a rubber, plastic or textile, or other common materials for straps. The strap can furthermore be stretchable.

In a related embodiment, a connecting component 102 can utilize one or more points of contact to secure a handheld electronic device, a dashboard mount case, wallet case, folding case, bumper case or other cases designed to hold handheld electronic devices.

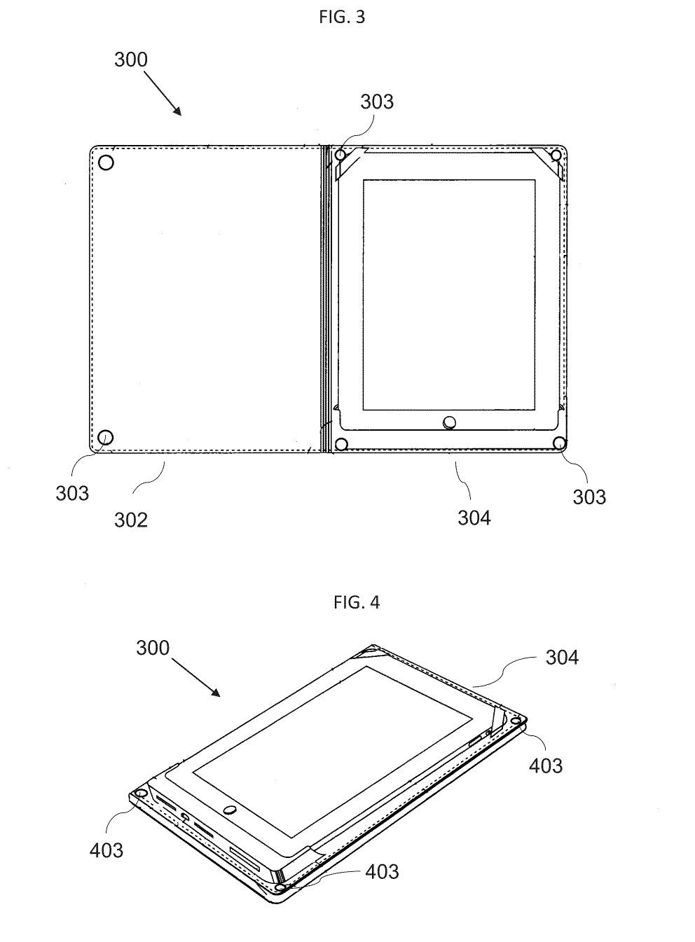

FIG. 3 shows an example of such an embodiment of a secure mounting device 300, wherein a connecting component 302, is connected with a device holder 304, which can hold an electronic device mounted in front of a control panel and secured in a joint on the control panel. The secure mounting device 300 has hooking points 303, that can secure the secure mounting device 300 to mounts or connection points on a control panel.

FIG. 4 shows the example embodiment of the secure mounting device 300 in a folded-up configuration, suitable for use when removed from its position in the control panel. In this configuration with the hooking points 403 overlapping, the secure mounting device 300 can be secured to mounts or connection points on the control panel.

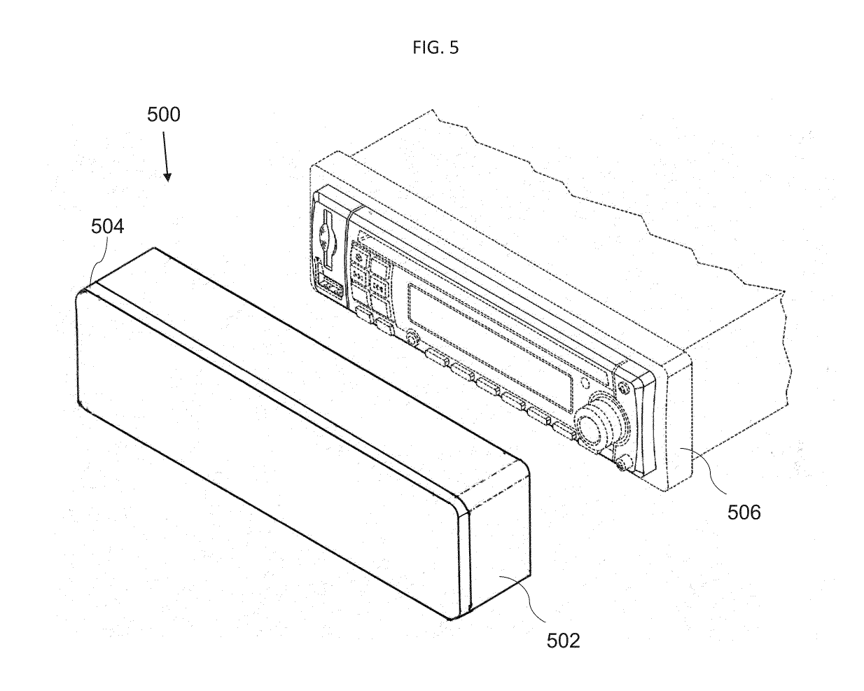

FIG. 5 shows an alternative embodiment, wherein a secure mounting device 500 is composed of a cover panel 504 and a connecting component in the form of side walls 502 that can slide over a control panel instrument 506, such as a radio, wherein the side walls 502 slide in and are mounted between the control panel instrument 506 and the control panel.

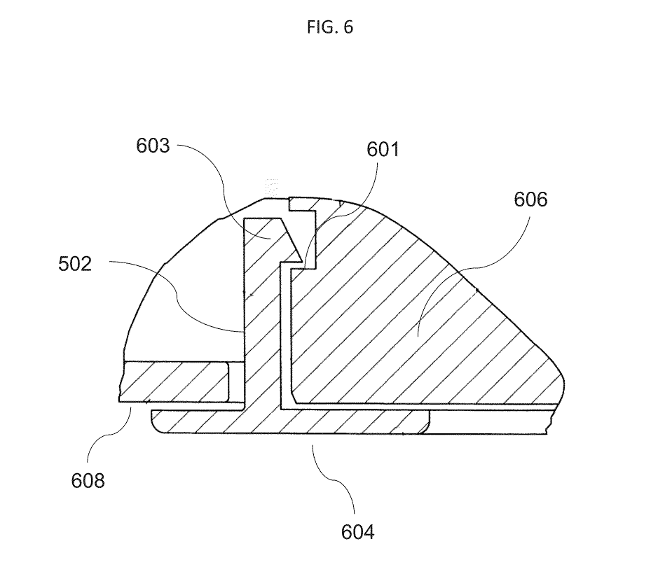

In a related embodiment, as shown in FIG. 6, a secure mounting device for a handheld electronic device can include a cover panel 604, and a locking component 603, which is connected at the end of a connecting component 502 of the secure mounting device, wherein the locking component 603 and the connecting component 502 can be passed through an opening between a control panel 608 and a control panel instrument 606, so that the locking component 603 locks to a locking surface 601, in order to secure the secure mounting device to the control panel 608.

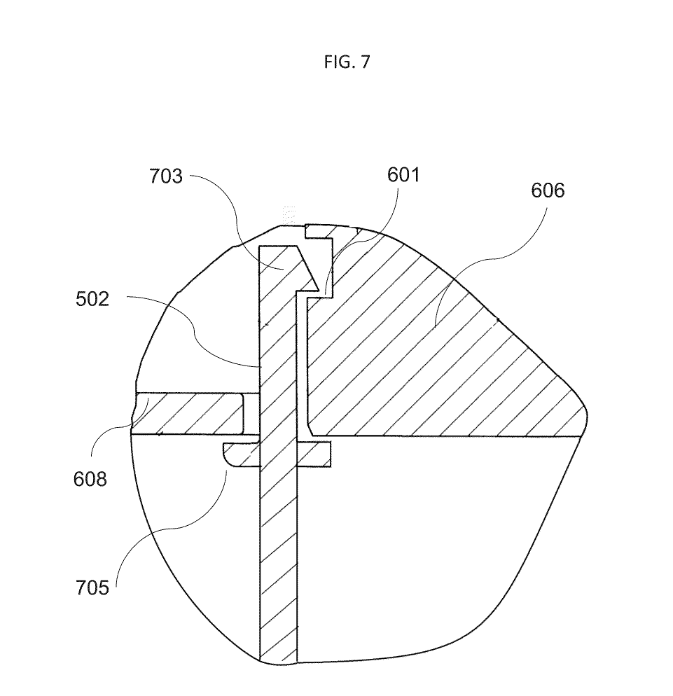

FIG. 7 shows a further related embodiment, which includes a locking stabilizer 705, which works together with the locking component 703, wherein the locking component 703 and the connecting component 502 can be passed through an opening between a control panel 608 and a control panel instrument 606, so that the locking component 703 locks to a locking surface 601, in order to secure the secure mounting device to the control panel 608.

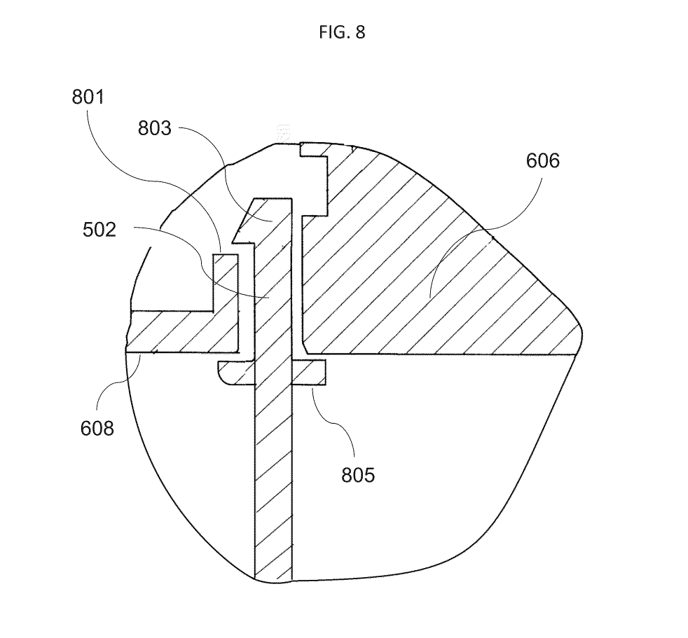

FIG. 8 shows a further related embodiment, which includes a locking stabilizer 805, which works together with the locking component 803, wherein the locking component 803 and the connecting component 502 can be passed through an opening between a control panel 608 and a control panel instrument 606, so that the locking component 803 locks to a locking surface 801, in order to secure the secure mounting device to the control panel 608.

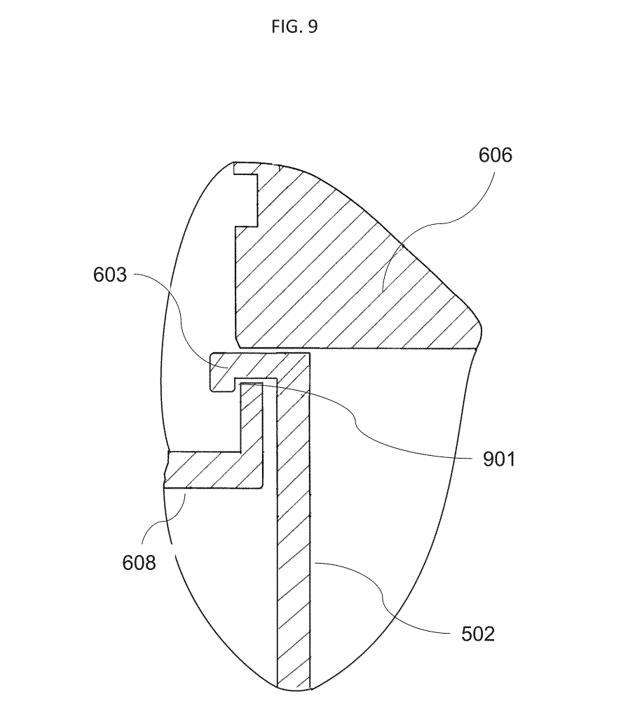

FIG. 9 shows a further related embodiment, wherein the locking component 603 and the connecting component 502 can be passed through an opening between a control panel 608 and a control panel instrument 606, so that the locking component 603 locks to a locking surface 901, in order to secure the secure mounting device to the control panel 608.

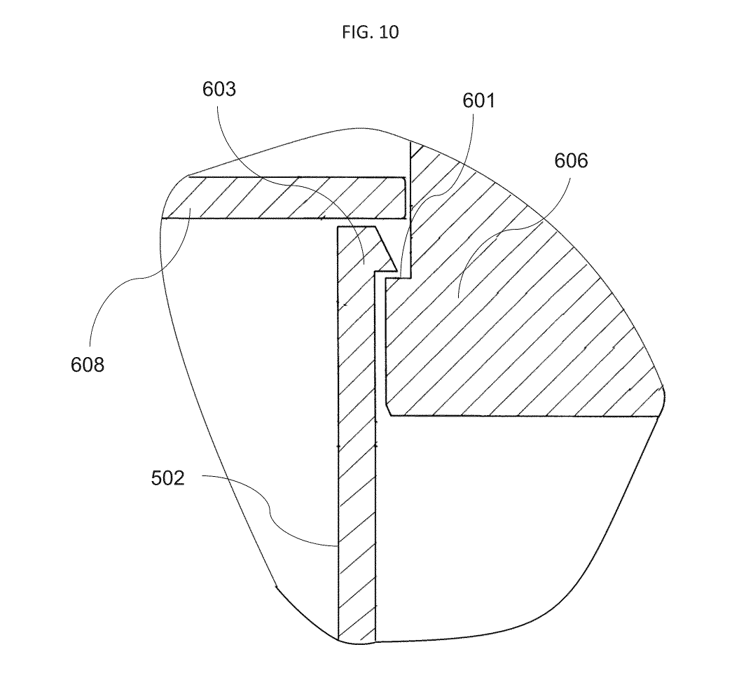

FIG. 10, shows a further related embodiment, wherein the locking component 603 and the connecting component 502 are locked in front of the control panel 608, whereby the locking component 603 locks to the locking surface 601, in order to secure the secure mounting device to the control panel 608.

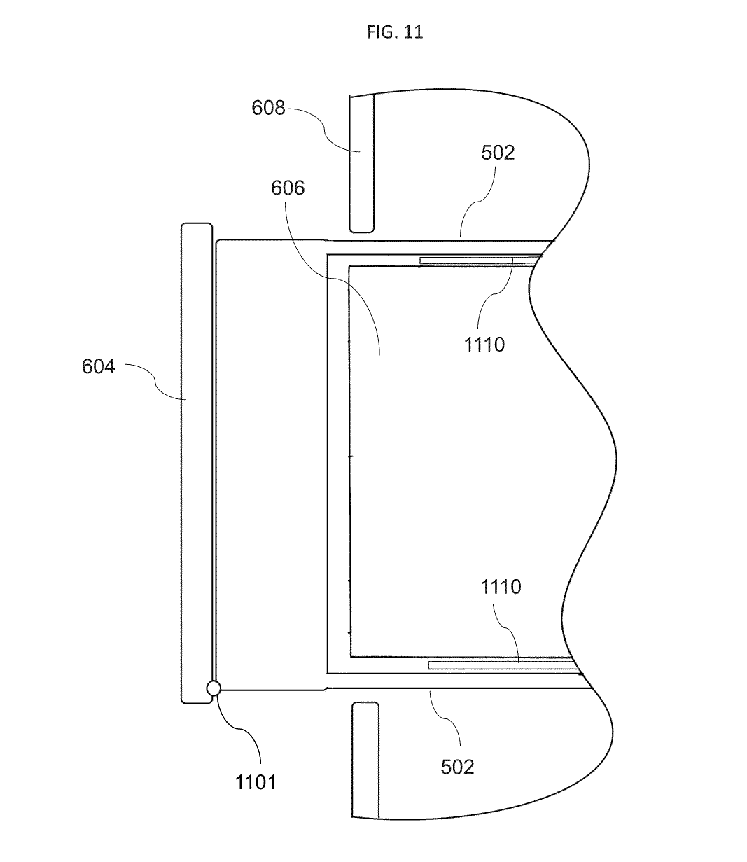

FIG. 11 shows a top cross-sectional view of a related embodiment, wherein the cover panel 604 is secured in place by the connecting component 502, which is glued to the control panel instrument 606, by a glue strip 1110, in order to secure the secure mounting device to the control panel 608.

In a related embodiment, the cover panel and side wall molding can be made of any flexible and solid material, such as different types of wood, plastics and metals, etc.

In further related embodiments, the cover panel material can be opaque, semi-transparent, transparent or clear.

In further related embodiments, the cover panel can be placed anywhere on a control panel, over a complete instrument control panel or integrated in a dashboard of a vehicle.

In further related embodiments, the cover panel can open in any direction, slide in any direction, slide and tilt in any direction or be removable to gain access to the instrument that needs control, while optionally holding a handheld electronic device.

In a further related embodiment, the cover panel can include an IR remote repeater for transmitting an IR signal to an IR receiver on a control panel behind the cover panel.

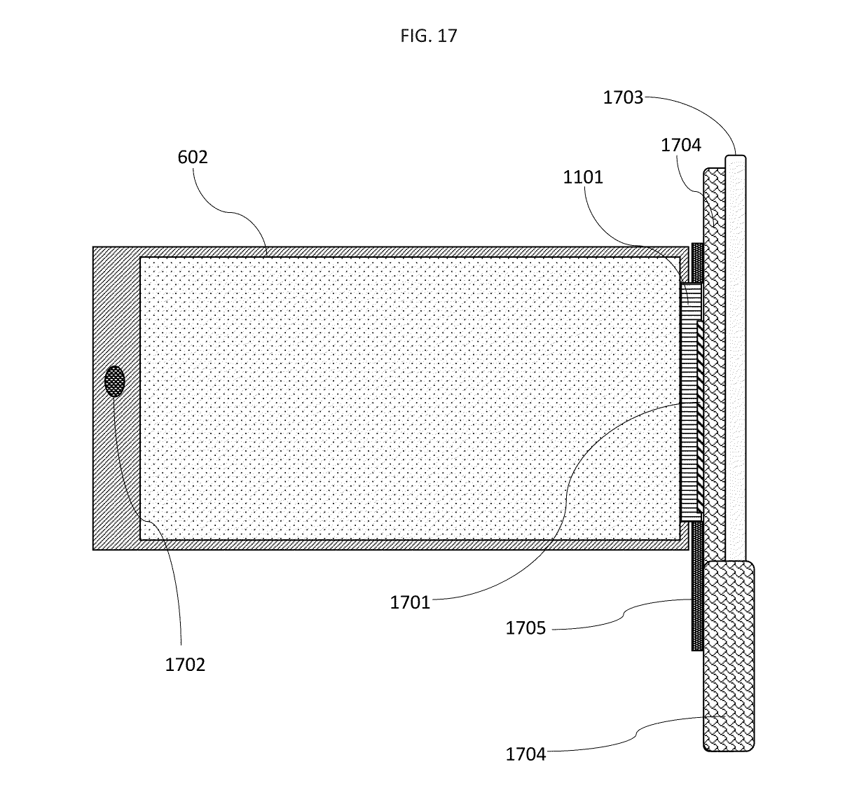

FIG. 17 illustrates such an embodiment, wherein a slide up or down hinge 1101 with a lockable position or semi locking system, mounted on a gliding rail 1705 inserted through a shaft connected to the cover panel 1704. The cover panel 1704 can be molded as a case to contain a handheld electronic device 1703.

FIG. 17 shows a front view of an embodiment of a secure mounting device, with an open cover panel 1704, showing a side view of the cover panel 1704.

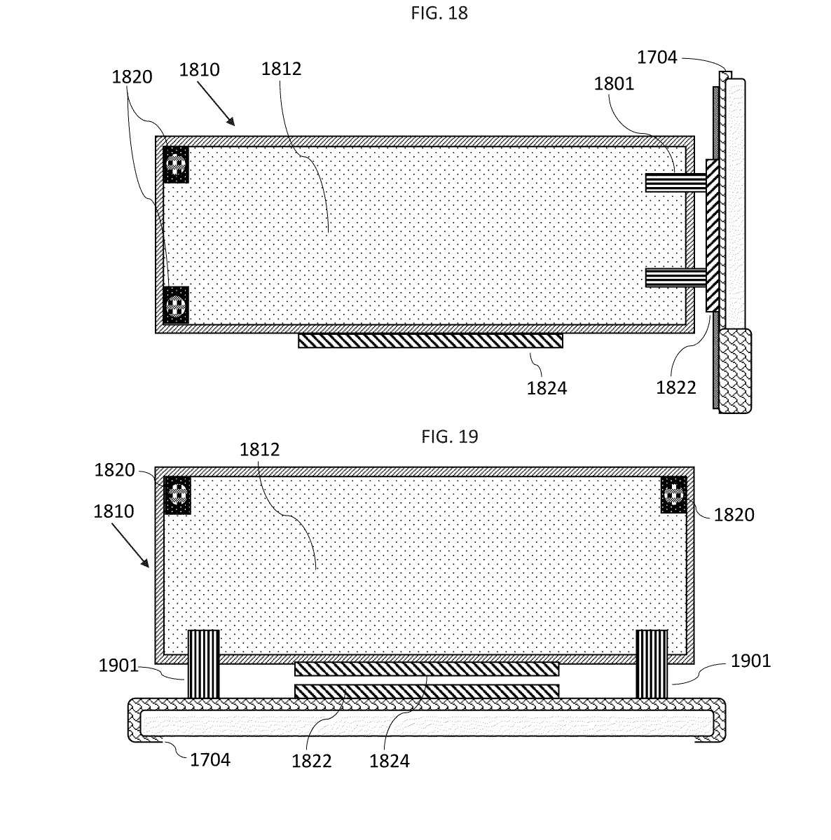

FIG. 18 illustrates a front view of a further related embodiment, wherein the cover panel 1704 can slide and/or tilt in any direction, and further include a removable hinge mechanism 1801, which can include any common hinge, such as concealed hinges, euro hinges or any other hinge mechanism that can allow the cover panel to slide and hold a touchscreen device properly in any angle or direction.

FIG. 18 shows a front view of an embodiment of a secure mounting device, with an open cover panel 1704, showing a side view of the cover panel 1704.

In a related embodiment, the cover panel 1704 can be attached to a media box 1810, which is insertable in an open cavity in a control panel for attachment. The media box 1810 can further include a box cavity 1812, which can be used for storage of personal electronic devices.

In additional related embodiments, the cover panel 1704 can fully or partially cover the control panel in order to provide the best utilization of space for containing an optional handheld electronic device of variable size.

In a further related embodiment, the cover panel 1704 can further include one or more optional lock mechanisms, such as a
a. Latch;
b. Push-to-lock, with push-to-release mechanism;
c. Magnetic locking system 1820;
d. Spring integrated into the hinge 1801; or
e. Other locking mechanisms
Whereby the cover panel can be secured when in the closed position

In a related embodiment, at least one electromagnetic lock 1820, can secure the cover panel in a closed position. The electromagnetic lock 1820 can be wirelessly controlled, such that it can be switched on and off via a mobile device.

FIG. 19 shows a related embodiment wherein a hinge mechanism 1901 is configured such that the cover panel opens by lowering in front of and underneath the media box 1810.

FIG. 19 shows a front view of an embodiment of a secure mounting device, with an open cover panel 1704, showing a top view of the cover panel 1704.

In a related embodiment, a wireless charging component 1822 can be mounted on the rear side of the cover panel 1704, such that it can charge the mobile device, which is placed in the cover panel 1704. The wireless charging component 1822 can for example employ the Qi inductive power standard.

In a related embodiment, a wireless charging component 1824 can be mounted underneath the media box 1810, such that it can charge mobile devices, which are placed in the box cavity 1812, inside the media box 1810.

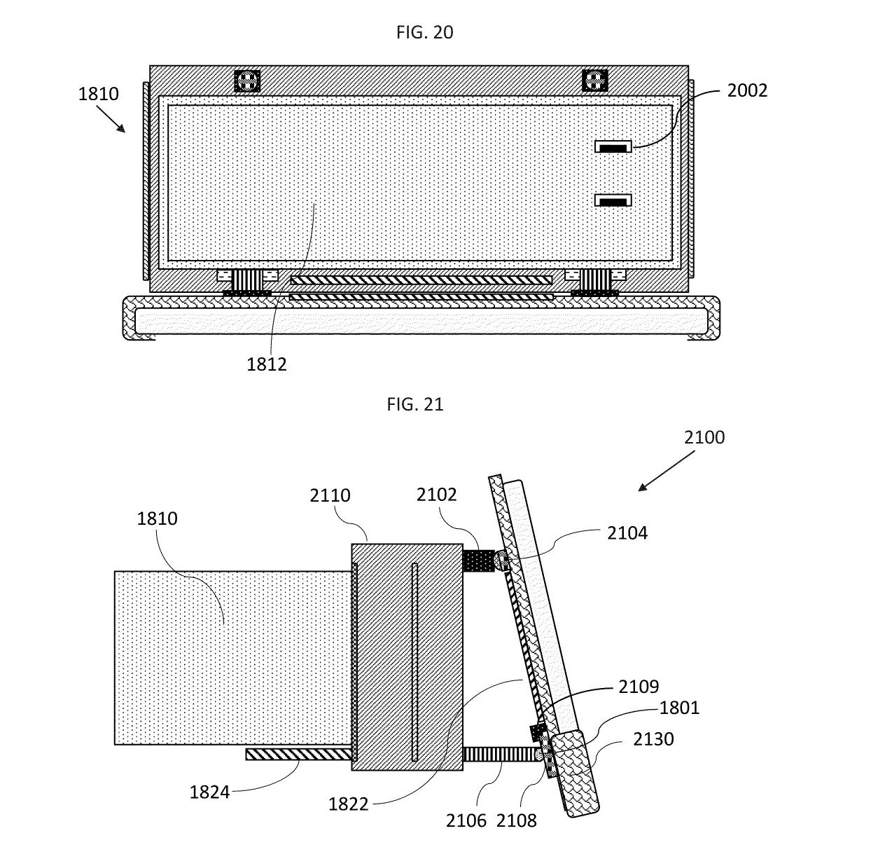

In a related embodiment, as illustrated in FIG. 20, at least one USB port 2002 can be placed inside the box cavity 1812 of the media box 1810, such that the USB port 2002 can be used to charge a mobile device via a USB cable.

In a related embodiment, as illustrated in FIG. 21, showing a side view, a secure mounting device 2100 can further include:
a. A molding 2110; which is attached around a front periphery of the media box 1810, and connects to a control panel to which the secure mounting device 2100 is mounted;
b. At least one upper extendable arm 2102, which is connected to the media box 1810 and can slide in and out of the media box 1810, and further can comprise an upper magnetic holder 2104 to connect to the upper part of the cover panel 2130. There can be two upper extendable arms 2102 such that each upper extendable arm 2102 is pivotally connected to respectively a left and right upper part of a rear of the cover panel 2130;
c. At least one lower extendable arm 2106, which is connected to the media box 1810 and can slide in and out of the media box 1810, and further can comprise a lower magnetic holder 2108 to connect to the lower part of cover panel 2130. There can be two lower extendable arms 2106, such that each lower extendable arm 2106 is pivotally connected to respectively a left and right lower part of a rear of the cover panel 2130;
d. At least one support clip 2109, molded into the cover panel 2130, to snap on to a front of the lower extendable arm 2106;
whereby the position of the cover panel can be adjusted by sliding the upper and lower extendable arms 2102 2106 to selected positions.

FIG. 21 shows a side view of an embodiment of a secure mounting device 2100, with a closed cover panel 2130, showing a side view of the cover panel 2130, in a vertically tilted state.

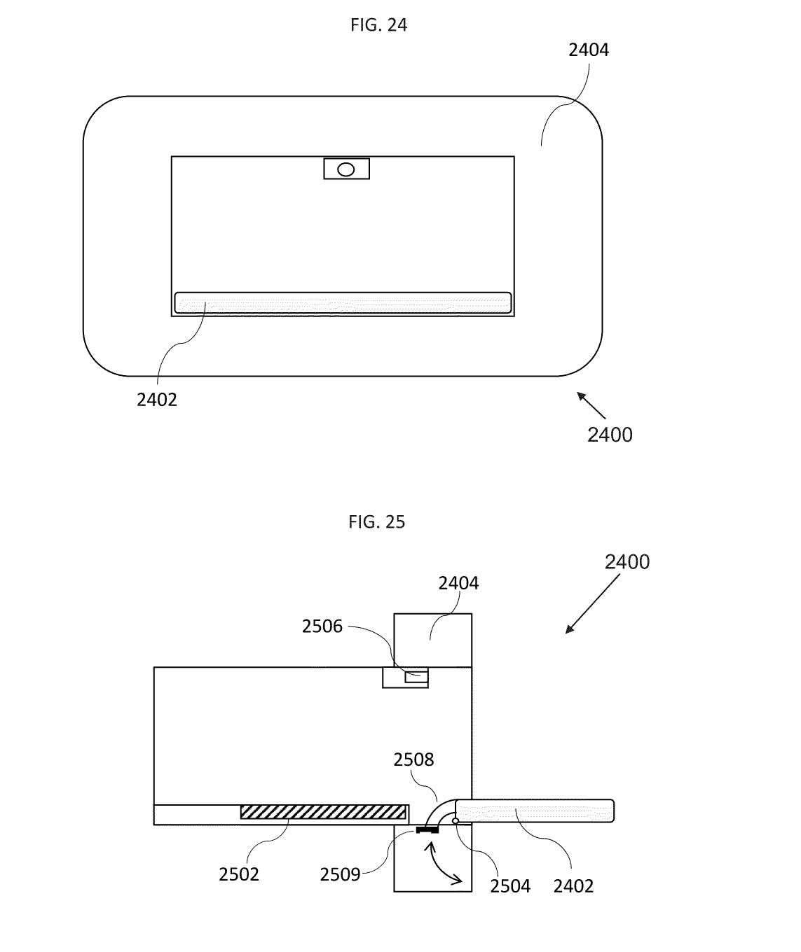

In a related embodiment, FIG. 24 shows a secure mounting device 2400 with a hinge mounted cover panel 2402, mounted recessed inside or flush to molding 2404.

In a related embodiment, the molding 2404 or sidewall can be mounted with common screws, adhesive, or magnets, attaching to the control panel or directly to an instrument in the control panel.

FIG. 24 shows a front view of an embodiment of a secure mounting device, with an open cover panel 2402, showing a top view of the cover panel 2402.

In a related embodiment, FIG. 25 shows a center cut side view of the secure mounting device 2400, including:
a. a wireless charger 2502;
b. a touchscreen cover panel 2402, shown open, which is mounted with a hinge 2504 which is connected to a first end of a downward curving arm 2508 with a stopper pad 2509, connected to a second end of the downward curving arm, such that the stopper pad 2509 is configured to stop movement of the control panel 2402 when the control panel 2402 reaches a closed position, by the stopper pad 2509 being stopped by an inside surface of a front part of the molding 2404;
c. an electronic lock 2506, which can be released by selecting a function on the touchscreen.

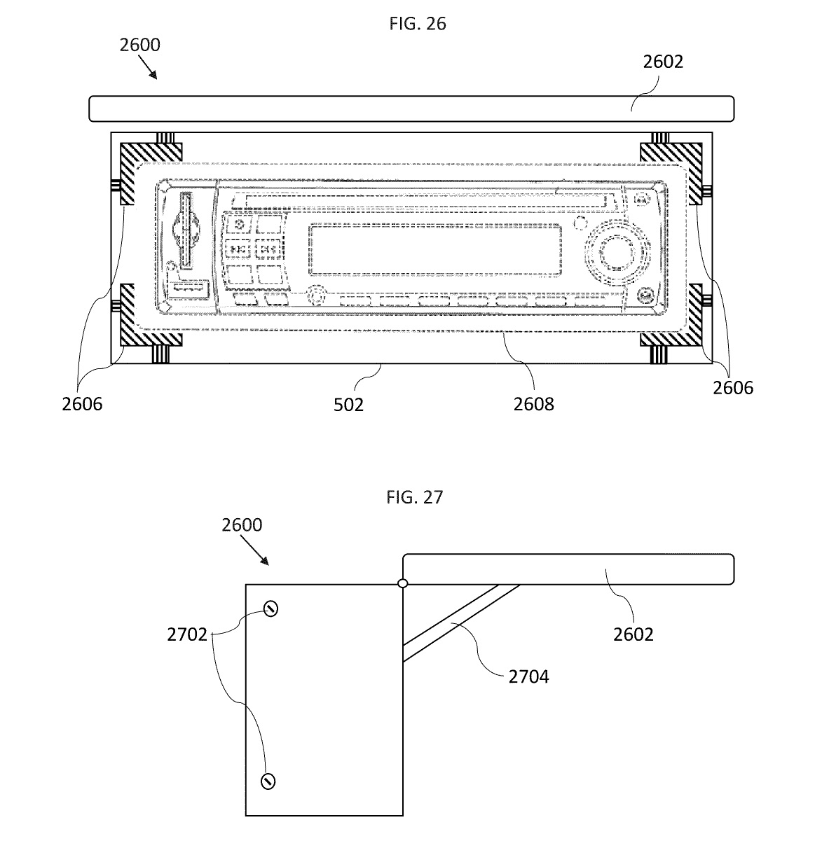

In a related embodiment, FIG. 26 shows a front view of a secure mounting device 2600, further including a top mounted touchscreen cover panel 2602 (shown open), mounted to sidewalls 502, which further comprise inner mounted corner gripper points 2606, which can support and secure an instrument 2608, which is positioned inside sidewalls 502.

In a related embodiment, FIG. 27 shows a side view of the secure mounting device 2600 of FIG. 27, including tightening screws 2702 for adjusting the hold and position of the gripper points 2604 (shown in FIG. 26). The secure mounting device 2600 can further include a lifter support 2704, to hold open the touchscreen cover panel 2602.

In a further related embodiment, the cover panel can include a weatherproof sealing between the sidewall molding and the cover plate of the control panel instrument.

In a further related embodiment, the cover panel can be secured to a molding or border material that fits around a common cover plate of a control panel, so that the molding is flush against the control panel or dashboard surface, and can be secured by a connecting component, inserted in a joint wherein a thin insert of the connecting component can be secured directly to the control panel with adhesive, two-sided tape adhesive, an expanding hook clip, or other type of common fastening mechanism.

In a further related embodiment, in order to accommodate the many different dashboard or control panel designs that will frequently change for any given vehicle make, and model, the molding or border can be designed with a unified shape to hold the cover panel in place for a wide range of different dashboards and control panels.

In further related embodiments, the cover panel can additionally slide tilt and lock in any direction or angle degree, to obtain the best possible position in holding a display device on any control panel.

In a further related embodiment, the parts of the molding that come in contact with the radio or control panel, can have an anti-grip polymer rubber, two-sided adhesive or soft cushion material to limit damage or scratching of the surface of the control panel, and to increase the strength of the grip to the faceplate.

In a further related embodiment, common radio or control panel removal key points, which are common on some automotive vehicles, can be utilized as mounting points for the cover panel. Typical round key removal points, can receive an insertable plastic locking mechanism, to secure the mount to the radio or other control panel surfaces.

In a further related embodiment, access key points that are usually flat or other shaped key entry release mechanisms, designed to remove the radio or other control panel, can provide a locking mechanism for a customized locking component, to establish a secure mounting point.

In a further related embodiment, some motor vehicles utilize a plastic molding that covers the perimeter of the radio or control panel, which can be utilized as a securing point, by inserting a plastic grooved hook system that can attach in between the plastic molding and the cover panel on the radio or control panel.

In a further related embodiment, the cover panel can have internal backlighting, for example inside the cover for a translucent LCD panel, to illuminate the control panel or an instrument in the control panel.

In a further related embodiment, illustrated in FIG. 13, the front cover panel 1204 can be a monitor display that is an LED, LCD, translucent, flexible, touchscreen display, or made of any display technologies with a fully integrated processing unit, with all the features commonly used in tablets and smart phone devices. GPS, Bluetooth, compass, cellular phone, Internet, etc. FIG. 13 illustrates variant embodiments, wherein the front cover panel 1204, shown closed, can be either solid 1210 or translucent 1212.

In a further related embodiment, the front cover panel 1204 can include a switchable smart glass or film section for light management and or visibility, in conjunction with touchscreen, translucent displays, LCD displays or any other display technologies. The switchable smart glass can be configured to switch between a transparent mode, and an opaque mode, such that visibility of the control panel can be adjusted.

In yet a further related embodiment, display components of a front cover panel 1204 can be in a plurality of distinct sizes and dimensions;

In yet a further related embodiment, the front cover panel 1204 can include a touchscreen digitizer.

In a first example embodiment, the front cover panel 1204 can include a large translucent smart glass area, covering 60% of the cover panel 1204, a smaller display covering 20%, and a touchscreen digitizer covering 20%.

In a second example embodiment, the front cover panel 1204 can include a translucent cover panel with 20% switching smart glass, 20% LCD display, and 60% touchscreen digitizer.

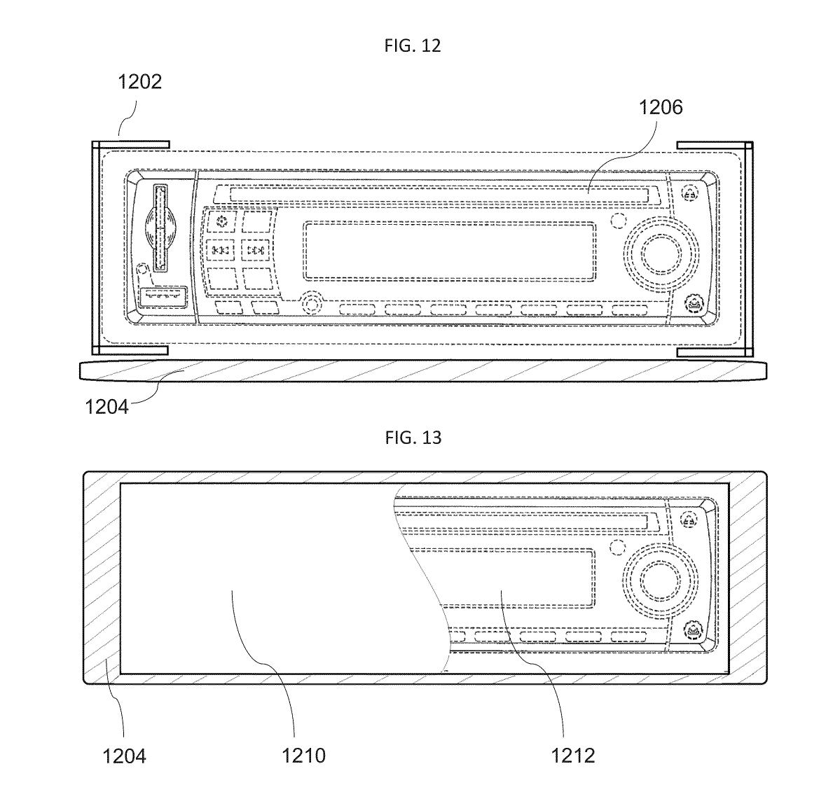

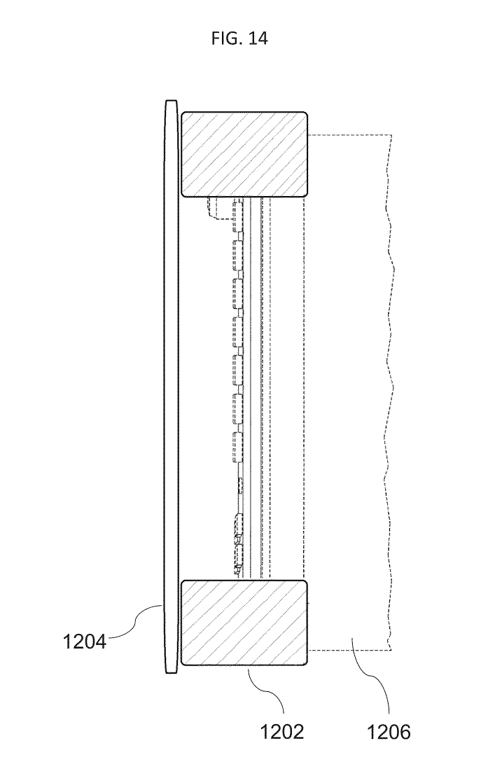

FIG. 12 illustrates a related embodiment, wherein the front cover panel 1204 is open, allowing access to the control panel component 1206.

In a further related embodiment, a wireless charging unit or wireless power supply circuit can be integrated into the front cover 1204 or sidewall molding 1202 that is attached to a control panel.

In a further related embodiment, power can be supplied via a ribbon cable that goes through a joint, behind the control panel to the front of the secure mounting device, and optionally an audio connection to the radio and or amplifier audio input can also be provided via the ribbon cable.

In a further related embodiment, a wireless audio interface to the audio signal from the audio connection can provide manual or automatic switchover, to utilize the speakers in the vehicle.

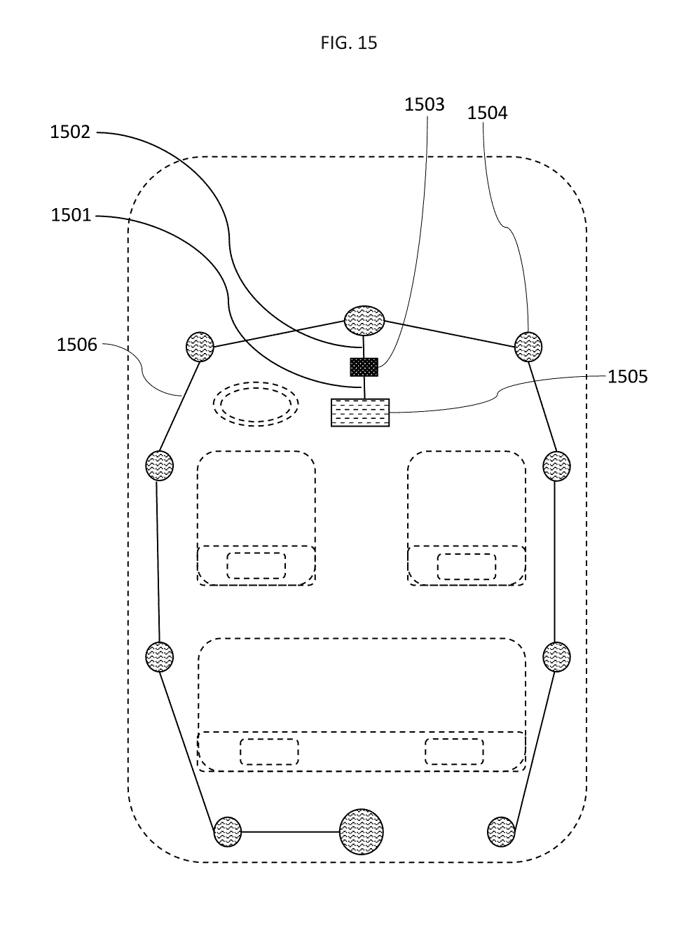

In a further related embodiment, as illustrated in FIG. 15, wireless audio transmitted via a wireless network or Bluetooth interface can be provided by a cover panel touchscreen display or handheld device. By utilizing an external wireless audio, wireless network, or Bluetooth receiver interface to the vehicle audio system 1505 or audio external amplifier, the cover panel touchscreen display can automatically switch over via the audio switchover device 1503 to one or more speakers 1504.

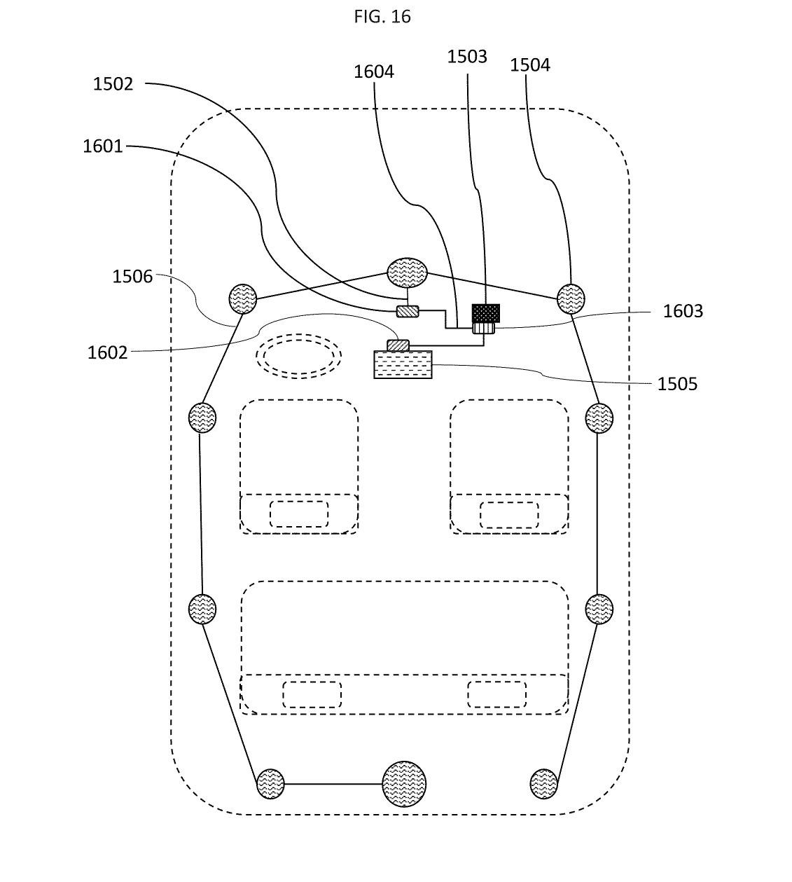

In further related embodiments, as illustrated in FIG. 16, the audio switchover device 1503 can further include one or more optional circuits, such as:
a. A changeover circuit directly connected in between the vehicle amplified audio speaker output terminals 1602, and one or more speakers 1504;
b. A built-in audio amplifier circuit, to power the vehicle speaker 1504 system independently;
c. Interface to one or more audio output channels from the vehicles audio system in between the external audio amplifier system, with a changeover audio circuit directly connected in series or parallel for audio overlays;
d. A combination of (a), (b), (c), to achieve manual or automatic audio changeover, with a connection interface directly connected to the speaker circuit, USB interface, wireless, Bluetooth or low-power outputs or inputs of a vehicle audio system;
e. Analog or digital audio detection circuit, to automatically switch over only when the device is transmitting audio signals;
f. Delay settable time-period, to automatically switch back and forth from the vehicle audio system to the electronic device audio system;
g. Soft audio change over circuit;
h. multichannel surround sound processor for multiple speakers system;
i. Sound echo canceling technology or sound turned off when utilizing one or more microphone;
j. surround sound calibration, savable memory circuit
k. Other commonly known audio interfaces that are utilized in amplifiers, communication, or audio circuit designs.

In a related embodiment for simplifying installation, the audio switchover device 1503 can have screw type terminals to connect and interface in between cut speaker wires. A first side of the audio switch over interface 1503 can be connected to a vehicle audio system output wire harness 1501 and second side of the audio switch over interface 1503 can be connected to the speaker wire harness 1506, thereby completing the installation.

A related embodiment can further include a custom manufactured pass-through cable 1604, designed to fit any given vehicle or aftermarket audio system, wherein the pass-through cable 1604 includes a matching male or female plug 1601 on one side and a matching female or male plug 1602 on the other side of the cable, with a universal split off connection plug 1603, to connect or interface with the audio automatic switchover interface 1503. The pass-through cable 1604 can allow for quicker installation and clean universal connection to any given vehicle audio system 1505.

In a related embodiment, the audio switchover device 1503 can control three or more audio channels installed in a vehicle.

In a related embodiment, the audio switchover device 1503 can be installed to multiple audio aftermarket or factory amplifiers, which can be installed in a vehicle, in one or a plurality of locations.

In a related embodiment, the audio switchover device 1503 can combine a high level audio channel in a vehicle with an audio low level subwoofer pre-amplifier channel. The combination of channels can be controlled via a wireless connection, such as Bluetooth or can be hardwired.

In a further related embodiment, the audio switchover device 1503 can further include a combination of wireless audio transmitted to one or more switchover devices.

In an example embodiment, a radio, with four speakers and one subwoofer speaker, can have a direct high level switchover device 1503 directly connected to the four speakers, and a low level audio switchover device connected in between the radio and the subwoofer amplifier, thereby keeping the subwoofer amplifier intact when switching over.

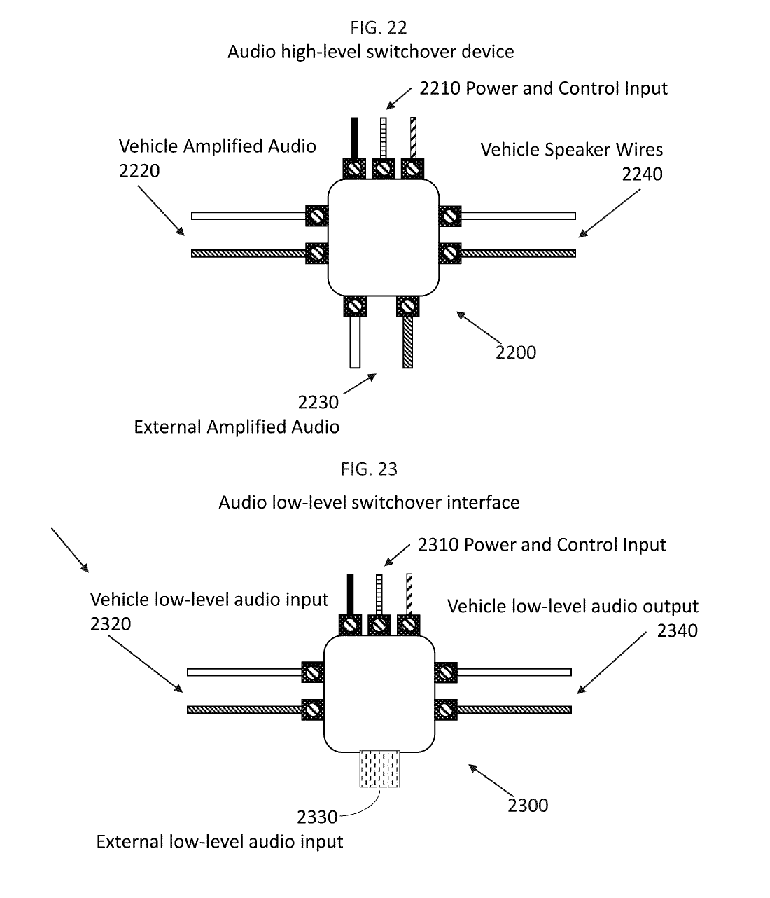

In an embodiment, as illustrated in FIG. 22, an audio high-level switch over device 2200, for switching over high-level amplified audio signals, can include:
a. Power and control input 2210, further including
   i. Negative ground;
   ii. A remote turn-on switchover connection;
   iii. Positive power;
b. Vehicle amplified audio 2220;
c. External amplified audio 2230;
d. Vehicle speaker audio wires 2240;
Such that a high voltage connection to the remote turn-on switchover connection causes a connection of the vehicle speaker audio wires 2240 to the external amplified audio 2230, and a zero voltage connection to the remote turn-on switchover connection causes a connection of the vehicle speaker audio wires 2240 to the vehicle amplified audio 2220.

In a related embodiment, the vehicle amplified audio 2220 can be a control panel amplified audio connection and the vehicle speaker audio wires 2240 can be a control panel speaker audio connection.

In an embodiment, as illustrated in FIG. 23, an audio low-level switch over device 2300, for switching over low-level pre-amplifier audio signals, can include:
a. Power and control input 2310, further including
   i. Negative ground;
   ii. A remote turn-on switchover connection;
   iii. Positive power;
b. Vehicle low-level audio input 2320;
c. External low-level audio input 2330; which can be connected via an RCA jack connection;
d. Vehicle low-level audio output 2340;
Such that a high voltage connection to the remote turn-on switchover connection causes a connection of the vehicle low-level audio output 2340 to the external low-level audio input 2330, and zero voltage connection to the remote turn-on switchover connection causes a connection of the vehicle low-level audio output 2340 to the control panel low-level audio input 2320.

In a related embodiment, the vehicle low-level audio input 2320 can be a control panel low-level audio input and the vehicle low-level audio output 2340 can be a control panel low-level audio output.

In an embodiment, EQ adjustment controls can be provided for an audio switch over device for cutting off non-used frequencies, for higher efficiency and more power utilization of the speaker system, and for removing low-frequency distortions.

In an embodiment, a hardwired USB or wireless connection can connect directly to the audio switchover device from a touchscreen holder or electronic device.

In an embodiment, when a radio/audio system of the vehicle is turned off and the vehicle's ignition is turned on, the switchover device can be powered on and switched to an external amplifier. Then, when the radio is turned on, the switchover device can switch to an internal amplifier, which is connected to the radio. A conventional voltage threshold detector can be used to detect if the internal amplifier of the radio is turned on, for example via a connection to an amplifier output, a remote turn-on output, an antenna turn-on output, or similar output.

In a related embodiment, the audio switchover device can be configured such that when a radio/audio system of a control panel is turned off and power to the control panel is turned on, the audio switch-over device is connected to an external audio input, which for example can be an external amplified audio 2230 or an external low-level audio input 2330; and when the radio/audio system is turned on and power to the control panel is turned on, the audio switch-over device is connected to an internal audio input of the control panel, which for example can be a vehicle amplified audio 2220 or a vehicle low-level audio-input 2320.

In various related embodiments, a secure mounting device can function as a docking station for a vehicle.

In various related embodiments, a secure mounting device, which is mounted to a primary control panel, can function as an extended control panel for the primary control panel.

In an example embodiment, the secure mounting device functions as a smart phone docking station, that is connected to the speakers of a vehicle, such that the smart phone for example connects to a switch over device 1503 via USB or Bluetooth.

In related embodiment, a secure mounting device can be installed on industrial instrument panels, such that the cover panel is a translucent display. In alternative embodiment, the control panel can be equipment, medical equipment, and industrial or scientific control devices that can benefit from a panel opening to quickly gain access or control a device, or in order to provide a display on the control panel for displaying real-time additional information.

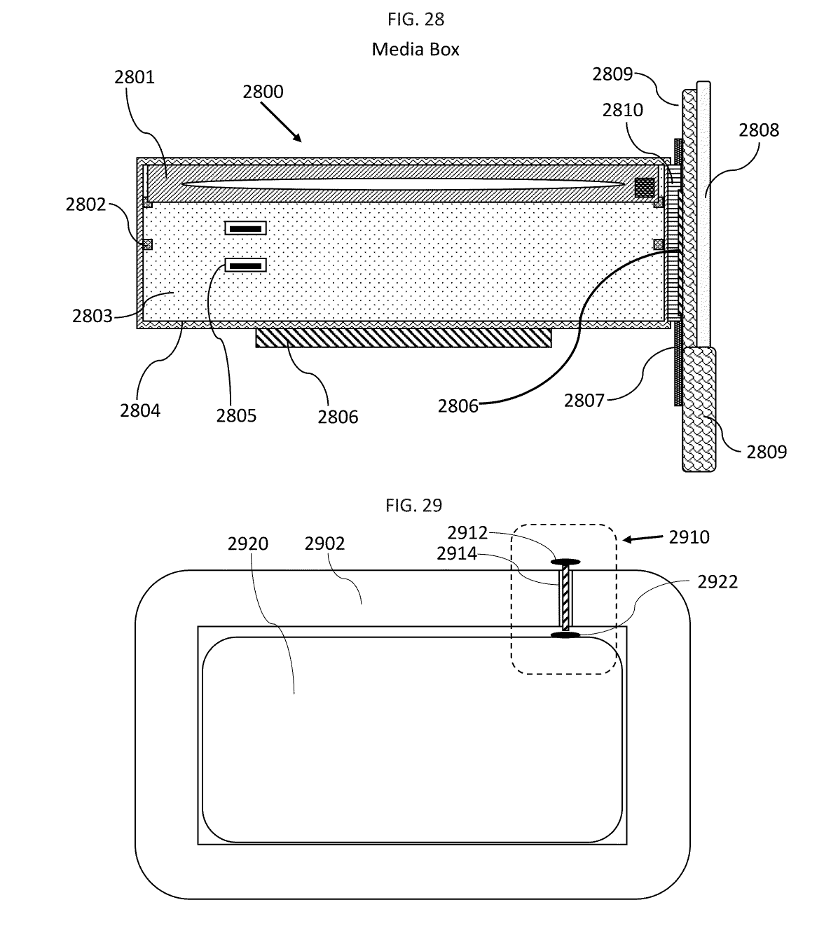

In an embodiment, as illustrated in FIG. 28, a secure mounting device can be configured as a media server box 2800, which includes a wireless charger 2806, and can be designed to fit in a standard single DIN, double DIN, or any predetermined slot in a control panel to replace the radio head unit. In addition, the media server box 2800 can be a stand-alone unit, or designed to fit in any opening, such as for example a glove box of a vehicle.

FIG. 28 shows a front view of an embodiment of a secure mounting device 2800, with an open cover panel 2809, showing a side view of the cover panel 2809.

The media server box 2800 can include a combination of one or more of:
a. A box cavity 2803, for storing one or more electronic devices. The box cavity 2803 can further include rubberized bottom cushioning to keep items from sliding or moving around, and have built-in radiofrequency and or magnetic shielding;
b. A wireless charger 2806, in the form of an industry-standard wireless power charging system or other wireless charging circuit design, located under the box cavity and behind the cover panel 2809, which can conveniently charge electronic devices, including cellphones, touchscreen devices 2808 and/or batteries with built-in wireless power receiving charger circuits;
c. One or more USB ports 2805, a USB hub controller, and/or other data transfer interface technologies, positioned inside the box cavity;
d. A slide-out media caddy 2801 for standard solid-state storage media, hard drives, and or optical drives, with an optional built-in SATA to USB converter or other converters. The slide out media caddy 2801 can have built-in radiofrequency and or magnetic shielding, and include a conventional lock in and/or release push button;
e. Side mounted rails 2802, mounted in box cavity 2803, to align the media caddy 2801 when sliding such that the media caddy interconnects with one of the USB ports 2805 located inside the box cavity 2803;
f. A cover panel 2809 or front cover door, which can open in any direction. The front cover panel 2809 can further include
   i. water or weather proof sealing;
   ii. A Locking mechanism, utilizing commonly known locking mechanisms, such as key lock, push in push out release, magnetic lock, electronic lock with optional keypad code entry, Bluetooth locking interface, interface with external or integrated touchscreen devices 2808 to lock or unlock with or without code, etc.;
   iii. A Touchscreen 2808 either self-contained or integrated with the media server;
g. A sliding hinge 2810 mounted on a lockable sliding rail 2807, which is connected to the cover panel 2809, and can be designed to hold an oversized tablet device. The sliding hinge 2810 can be designed for convenient positioning of the cover panel 2809, such that it can slide in a left right direction, or as shown in FIG. 28, in an up or down direction;
h. an IR remote repeater to operate the IR codes when interfacing with the touchscreen display 2808 to control an instrument with an IR remote interface, located on the backside of the cover panel;
i. Satellite or HD radio tuner devices with a wireless or USB interface;
j. Other commonly known add-on components for media servers.

In a related embodiment, the cover panel 2809 can be molded to include a holder for a touchscreen device 2808 or designed to be integrated flush mounted with the face of the touchscreen device 2808 into the cover panel material, with button mechanism extenders to mechanically activate side mounted buttons on a touchscreen device on the face or sides of the cover panel, to allow complete control of a touchscreen device, when embedded in the cover panel material or layered as shown in FIG. 28. The touchscreen device holder can be configured to be any predetermined size or portion of the cover panel 2809.

In a related embodiment, the cover panel 2809 can be removable.

In a related embodiment, the media server box 2800 can support external modular components to be attached on the outside of the media server box 2800, and connected via communication ports located on the outside of the media server box 2800.

In a related embodiment, common electronic device sensors, such as an accelerometer, can be utilized to detect when the cover panel is opened and closed, and, upon detection, activate the audio automatic switchover device, or set an alarm off at a remote location, or on the touchscreen device, to deter theft.

In a related embodiment, as illustrated in FIG. 29, a cover panel 2902 containing an electronic device 2920, such as a tablet, can further comprise a mechanical button actuator 2910, comprising an external button 2912, and a shaft 2914, such that the external button 2912 is connected to an outer end of the shaft 2914, and an inner end of the shaft 2914 is connected to or adjacent to a device button 2922 of the electronic device 2920, such that when a user depresses the external button 2912 this, via the shaft 2914, causes the device button 2922 to be depressed.

FIG. 29 shows a center-cut front view of an embodiment of a cover panel 2902.

In various embodiments, the secure mounting device can be manufactured by use of 3D-printer technology, in order to rapidly manufacture a large number of variations for different vehicle make/model combinations.

In the various embodiments of this invention, the secure mounting device can be placed in any location where there is benefit from having an attachable touchscreen cover panel, which can open to gain access to an underlying instrument control panel.

A method of securing a handheld device to a control panel can include:
a. Inserting a locking component of a secure mounting device through a gap in the control panel;
b. Securing the locking component in place by placing a locking component in a locked position in a locking surface;
c. Placing a mobile electronic device in a holder in the secure mounting device;
d. Adjusting the position and viewing angle of the secure mounting device that is holding the mobile electronic device.

An alternative method of securing a handheld device to a control panel can include:
a. attaching a secure mounting device directly to the outside perimeter of a control panel;
b. Placing a mobile electronic device in a holder in the secure mounting device;
c. Adjusting the position and viewing angle of the secure mounting device that is holding the mobile electronic device.

Here has thus been described a multitude of embodiments of a device for connecting handheld electronic devices to a control panel, and methods related thereto, which can be employed in numerous modes of usage.

The many features and advantages of the multitude of embodiments of the device and method for connecting handheld electronic devices to a control panel are apparent from the detailed specification, and thus, it is intended by the appended claims to cover all such features and advantages of the invention, which fall within the true spirit and scope of the invention.

Many such alternative configurations are readily apparent, and should be considered fully included in this specification and the claims appended hereto. Accordingly, since numerous modifications and variations will readily occur to those skilled in the art, it is not desired to limit the invention to the exact construction and operation illustrated and described, and thus, all modifications and equivalents may be resorted to, falling within the scope of the invention.

What is claimed is:

1. A secure mounting device for connecting a cover panel to a control panel, includes:
a. a connecting component; and
b. a cover panel, which is connected to the connecting component;
wherein the connecting component is attached to the control panel, such that the cover panel, is positioned in front of the control panel, such that the cover panel opens to allow access to the control panel.

2. The secure mounting device of claim 1, wherein the connecting components is configured with a flat and thin shape, such that it is inserted in a joint of the control panel.

3. The secure mounting device of claim 2, wherein the connecting components is configured as a strap.

4. The secure mounting device of claim 1, wherein the cover panel is configured to hold an electronic device.

5. The secure mounting device of claim 1, wherein the cover panel further comprises a display.

6. The secure mounting device of claim 1, wherein the connecting component further comprises a locking component, such that the locking component attaches to a locking surface of the control panel to secure the connecting component to the control panel.

7. The secure mounting device of claim 6, wherein the locking component is configured to pass through an opening in the control panel, such that the locking surface is behind a front of the control panel.

8. The secure mounting device of claim 1, wherein the cover panel is made of a transparent material.

9. The secure mounting device of claim 1, wherein the connecting component is a media box, which is inserted into a cavity in the control panel.

10. The secure mounting device of claim 9, further comprising a molding, which is attached around a front periphery of the media box, such that the molding connects with the control panel.

11. The secure mounting device of claim 9, wherein the media box further comprises a box cavity for storing an electronic device.

12. The secure mounting device of claim 1, wherein the cover panel further comprises a hinge mechanism, such that the cover panel opens, tilts, and slides vertically and horizontally.

13. The secure mounting device of claim 12, wherein the hinge mechanism is configured such that the cover panel opens by lowering in front of and underneath the media box.

14. The secure mounting device of claim 12, wherein the cover panel further comprises a locking mechanism for locking the cover panel in a closed position.

15. The secure mounting device of claim 14, wherein the locking mechanism is an electromagnetic lock.

16. The secure mounting device of claim 15, wherein the electromagnetic lock is configured to be wirelessly controlled, such that the electromagnetic lock is switched on and off via a mobile device.

17. The secure mounting device of claim 11, further comprising a wireless charging component, which is mounted underneath the box cavity, such that the wireless charging component charges the electronic device.

18. The secure mounting device of claim 5, further comprising a wireless charging component, which is mounted on a rear side of the cover panel, such that the wireless charging component charges the electronic device.

19. The secure mounting device of claim 11, further comprising:
a. at least one upper extendable arm, which is connected to the media box and slides in and out of the media box, such that the upper extendable arm is pivotally connected to an upper part of a rear of the cover panel; and
b. at least one lower extendable arm, which is connected to the media box and slides in and out of the media box, such that the lower extendable arm is pivotally connected to a lower part of a rear of the cover panel;
whereby the position of the cover panel is adjusted by sliding the upper and lower extendable locks to selected positions.

20. The secure mounting device of claim 1, wherein the cover panel further comprises an infrared remote repeater for transmitting an infrared signal to an infrared receiver on the control panel behind the cover panel.

21. The secure mounting device of claim 9, further comprising at least one audio switchover device.

22. The secure mounting device of claim 21, wherein the at least one audio switchover device, comprises an audio high-level switch over device, for switching over high-level amplified audio signals, further including:
a. power and control input, further including
i. a negative ground connection, connected to a negative ground from the control panel;
ii. a remote turn-on switchover connection; and
iii. a positive power connection, connected to a positive power from the control panel;
b. a control panel amplified audio connection, connected to an amplified audio signal from the control panel;
c. an external amplified audio connection; and
d. a control panel speaker audio connection, connected to a speaker connection in the control panel;
wherein a high voltage connection to the remote turn-on switchover connection causes a connection of the control panel speaker audio connection with the external amplified audio connection, and a zero voltage connection to the remote turn-on switchover connection causes a connection of the control panel speaker audio connection with the control panel amplified audio connection.

23. The secure mounting device of claim 21, wherein the at least one audio switchover device, comprises an audio low-level switch over device, for switching over low-level pre-amplifier audio signals, further including:
a. power and control input, further including:
i. a negative ground connection, connected to a negative ground from the control panel;
ii. a remote turn-on switchover connection; and
iii. a positive power connection, connected to a positive power from the control panel;
b. a control panel low-level audio input, connected to a low-level audio signal from the control panel;
c. an external low-level audio input; and
d. a control panel low-level audio output, connected to a low-level amplifier input from the control panel;
wherein a high voltage connection to the remote turn-on switchover connection causes a connection of the control panel low-level audio output to the external low-level audio input, and a zero voltage connection to the remote turn-on switchover connection causes a connection of the control panel low-level audio output with the control panel low-level audio input.

24. The audio switchover device of claim 21, wherein the audio switchover device is configured such that when a radio/audio system of the control panel is turned off and power to the control panel is turned on, the audio switch-over device is connected to an external audio input; and when the radio/audio system is turned on and power to the control panel is turned on, the audio switch-over device is connected to an internal audio input of the control panel.

25. The secure mounting device of claim 4, wherein a sensor of the electronic device is configured to detect when the cover panel is moved.

26. The secure mounting device of claim 9, wherein the media box further comprises a USB hub.

27. The secure mounting device of claim 4, wherein the cover panel further comprises a mechanical button actuator, comprising an external button and a shaft, such that the external button is connected to an outer end of the shaft, and an inner end of the shaft is connected to a device button of the electronic device, such that when a user depresses the external button this, via the shaft, causes the device button to be depressed.

28. The secure mounting device of claim 1, wherein the cover panel further comprises internal backlighting, such that the cover panel illuminates the control panel.

29. The secure mounting device of claim 1, wherein the cover panel further comprises a switchable smart glass section, such that the switchable smart section is configured to switch between a transparent mode and an opaque mode, such that visibility of the control panel is adjusted.

30. An audio switchover device, wherein the audio switchover device is configured such that when a radio/audio system of a control panel is turned off and power to the control panel is turned on, the audio switch-over device is connected to an external audio input; and when the radio/audio system is turned on and power to the control panel is turned on, the audio switch-over device is connected to an internal audio input of the control panel.

31. A secure mounting device for connecting a cover panel with a media box to a control panel, includes:
a. a media box, further comprising a box cavity for storing an electronic device; and
b. a cover panel, which is connected to the connecting component;
wherein the media box is inserted into a cavity of the control panel, such that the cover panel, is positioned in front of the control panel, such that the cover panel opens to allow access to the control panel.
